(19) United States
(12) Patent Application Publication
(10) Pub. No.: US 2021/0225622 A1
(43) Pub. Date: Jul. 22, 2021

(54) SUBSTRATE TREATMENT APPARATUS AND SUBSTRATE TREATMENT METHOD FOR MONITORING INTEGRATED VALUE

(71) Applicant: ASM IP Holding B.V., Almere (NL)

(72) Inventor: Fumitaka Shoji, Kawasaki-shi (JP)

(21) Appl. No.: 17/147,827

(22) Filed: Jan. 13, 2021

Related U.S. Application Data
(60) Provisional application No. 62/962,799, filed on Jan. 17, 2020.

(51) Int. Cl. H01J 37/32; C23C 16/455; C23C 16/52

(52) U.S. Cl. CPC H01J 37/32935; H01J 37/32174; H01J 2237/332; C23C 16/45544; C23C 16/52; H01J 37/32449

(57) ABSTRACT

Examples of a substrate treatment apparatus include an output device configured to output a plasma-related signal which is a signal obtained in association with plasma treatment used for the substrate treatment, and a controller configured to monitor an integrated value of the plasma-related signal received directly or indirectly from the output device.

### CROSS-REFERENCE TO RELATED APPLICATIONS

This application claims the benefit of and priority to U.S. Provisional Application No. 62/962,799, filed on Jan. 17, 2020 in the United States Patent and Trademark Office, the disclosure of which is incorporated herein in its entirety by reference.

### TECHNICAL FIELD

Examples are described which relate to a substrate treatment apparatus and a substrate treatment method.

### BACKGROUND

In Plasma-Enhanced Atomic Layer Deposition (PE-ALD), film-forming treatment is performed until a desired film thickness is obtained, by repeating the following steps in the following order of: a feed step (source feed) of making a film-forming material adsorb onto a wafer surface; a purge step (source purge) of discharging an excess film-forming material after the adsorption of the film-forming material onto the wafer surface has been saturated; and a reaction step (RF On) of forming radicalized reactants by a plasma which has been generated by a radio frequency power, making the reactants react with the film-forming material which has adsorbed to the wafer, and forming a film in a unit of an atomic layer.

In order to monitor that a normal film is formed while the plasma is generated, such factors are occasionally measured as a magnitude of a reflected wave power of the radio frequency power, and a luminescence intensity of the plasma. For example, the monitoring of the reflected wave power makes it possible to find a problem that a traveling wave power which is effectively applied to a shower head becomes small by a large reflected wave power, and that a desired film quality cannot be thereby obtained. For example, it becomes possible to issue an alarm or to stop the apparatus, when the maximum value of the reflected wave power has exceeded a threshold value.

A time period during which the plasma is generated in the PE-ALD film formation is generally about 0.1 seconds to about several seconds at longest. When the impedance matching of radio frequency power is performed electronically instantaneously, the value of the large reflected wave power converges sufficiently quickly, and there is no practical problem. However, in the above example, if the maximum value of the reflected wave power is large, the maximum value results in being detected as the alarm.

The case is not limited to the above example, and various technologies for monitoring that the substrate treatment is performed normally have been considered. However, in those technologies, there has been a problem that an unnecessary alarm is issued, or that the substrate treatment cannot be monitored with high accuracy.

### SUMMARY

Some examples described herein may address the above-described problems. Some examples described herein may provide a substrate treatment apparatus and a substrate treatment method which make it possible to monitor the process with high accuracy.

In some examples, a substrate treatment apparatus includes an output device configured to output a plasma-related signal which is a signal obtained in association with plasma treatment, and a controller configured to monitor an integrated value of the plasma-related signal.

### BRIEF DESCRIPTION OF THE DRAWINGS

FIG. 1 is a view showing a structure example of a substrate treatment apparatus;

FIG. 2 is a flowchart which shows one example of the substrate treatment method;

FIG. 3 shows an example of waveforms of a traveling wave power and a reflected wave power;

FIG. 4 is a flowchart which shows another example of the substrate treatment method;

FIG. 5 is a diagram which shows an example of a PD voltage;

FIG. 6 is a diagram which shows a structure example of a substrate treatment apparatus according to another example;

FIG. 7 is a diagram which shows a structure example of a substrate treatment apparatus according to still another example; and

FIG. 8 is a flowchart which shows an example of a substrate treatment method using an apparatus of FIG. 7.

### DETAILED DESCRIPTION

A substrate treatment apparatus and a substrate treatment method will be described below with reference to the drawings. In some cases, the same or corresponding components will be denoted by the same reference numerals, and the repetition of the description will be omitted.

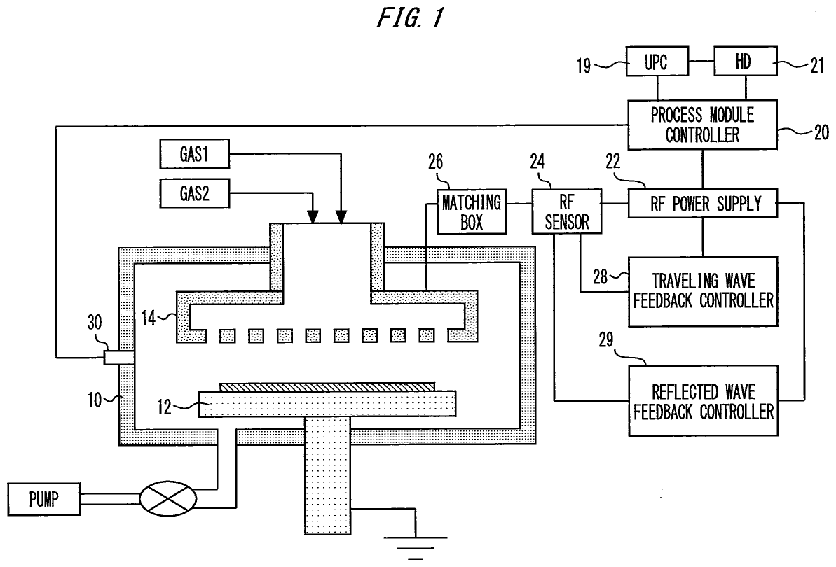

FIG. 1 is a view which shows a structure example of a substrate treatment apparatus. The substrate treatment apparatus includes a chamber 10; and a stage 12 and a shower head 14 which are provided in the chamber 10. The stage 12 and the shower head 14 provide a parallel plate structure. A gas is supplied from a gas source to a space between the stage 12 and the shower head 14, through a slit of the shower head 14. The gas is used for treatment of a substrate provided on the stage 12. The treatment of the substrate is, for example, film formation using plasma, etching using plasma, or film modification using plasma.

According to one example, a module which is used for the treatment of the substrates is controlled by a process module controller (PMC) 20. According to one example, a recipe is stored in the PMC 20, and the PMC 20 controls the module which is used for the substrate treatment, according to the recipe. The PMC 20 is, for example, a microcomputer. For example, a UPC (unique platform controller) 19 is connected to the PMC 20. According to one example, the UPC 19 functions as a controller for detection of abnormality. The UPC 19 can include a calculation unit, a storage unit, an alarm determination unit, and a sensor monitoring unit.

A data storage unit 21 is connected to the PMC 20 and the UPC 19. The data storage unit 21 is a portion in a hard disk, for example, which stores data necessary for the operation of the substrate treatment apparatus.

FIG. 1 illustrates a radio frequency power supply device 22 and a photodetector 30, as examples of modules which are controlled by the PMC 20.

The radio frequency power supply device 22 outputs a radio frequency power, on the basis of a command sent from the PMC 20. According to one example, the radio frequency power supply device 22 converts a DC voltage of a DC power supply by a DC/DC converter; converts DC to AC and amplifies the AC by an RF amplification unit; and supplies the obtained radio frequency power to a load such as a plasma load. According to one example, the radio frequency power which has been output from the radio frequency power supply device 22 is applied to the shower head 14 through an RF sensor 24 and a matching box 26.

A feedback controller 28 of a traveling wave power performs feedback control on the basis of a feedback value of the traveling wave power which has been detected by the RF sensor 24. A feedback controller 29 of a reflected wave power performs feedback control, on the basis of a feedback value of the reflected wave power which has been detected by the RF sensor 24.

The RF sensor 24 detects the traveling wave power, and transmits a signal which reflects a magnitude of the traveling wave power, to the feedback controller 28 of the traveling wave power. Furthermore, the RF sensor 24 detects the reflected wave power, and transmits a signal which reflects a magnitude of the reflected wave power, to the feedback controller 29 of the reflected wave power.

The matching box 26 can be a mechanical matcher or an electronic matcher. According to one example, the photodetector 30 converts light of plasma which is generated in a space between the stage 12 and the shower head 14, into a voltage, and outputs the voltage.

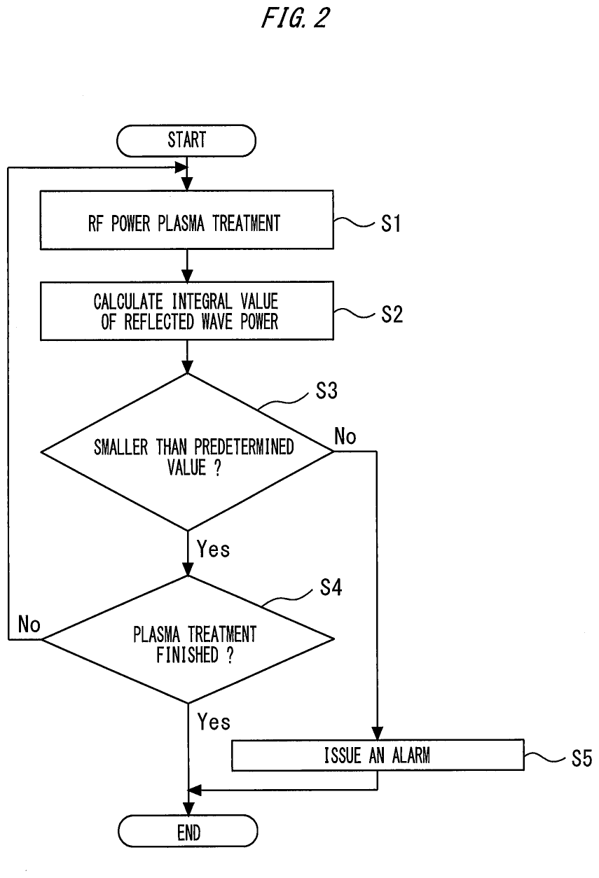

FIG. 2 is a flowchart which shows one example of the substrate treatment method. In this example, in the substrate treatment using plasma, the reflected wave power of the radio frequency power shall be an object to be monitored. Firstly, in step S1, the substrate is subjected to plasma treatment. Specifically, a radio frequency power is applied to the shower head 14 from the radio frequency power supply device 22 to generate plasma of the gas provided between the parallel plates, and the substrate on the stage 12 is treated with the plasma.

In step S2, an integral value of the reflected wave power is calculated which has been detected by the RF sensor 24. The feedback controller 29 of the reflected wave power calculates the integrated value of the reflected wave power; the PMC 20 that has received the signal which reflects the magnitude of the reflected wave power calculates the integrated value of the reflected wave power; or the UPC 19 which has received the signal calculates the integrated value of the reflected wave power. According to one example, the calculation unit of the UPC 19 calculates the integral value. An arbitrary controller can calculate the integral value. The integral value can be determined for one reflected wave power which is obtained for one pulse of the radio frequency power. According to another example, an integral value is determined for a plurality of reflected wave powers which are obtained for a plurality of pulses of the radio frequency power. According to further another example, the sum total of integrated values is determined for all the reflected wave powers which are obtained from the start to the end of the treatment of one substrate.

In step S3, it is determined whether a calculated integrated value is smaller than a predetermined value. An arbitrary controller can execute this determination. According to one example, the alarm determination unit of the UPC 19 compares the integrated value with a reference value which is stored in the storage unit or the data storage unit 21. Then, if the integrated value is equal to or larger than the reference value, the UPC 19 issues an alarm in step S5, or stops the substrate treatment. If the integrated value is smaller than the reference value, the UPC 19 proceeds the process to step S4; and if the plasma treatment should be continued on the basis of the recipe, the UPC 19 returns the process to step S1, and if the plasma treatment should be terminated, ends the process.

When the plasma treatment is performed as a part of the ALD process, the substrate treatment apparatus can determine whether the integrated value is smaller than the predetermined value, for every one cycle of the ALD. According to another example, the substrate treatment apparatus determines whether the sum total of integrated values which have been obtained in a plurality of cycles of ALD is smaller than a predetermined value.

Monitoring the integrated value makes it possible to monitor the process with high accuracy. For example, when the reflected wave power instantaneously has increased but has converged to 0 immediately, there is no actual harm to the process, and the integrated value becomes a sufficiently small value; and accordingly the process can be continued. According to one example, the substrate treatment apparatus can digitize the integrated value and monitor the digitized integrated value. The substrate treatment apparatus can compare the digitized integrated value with a predetermined reference value.

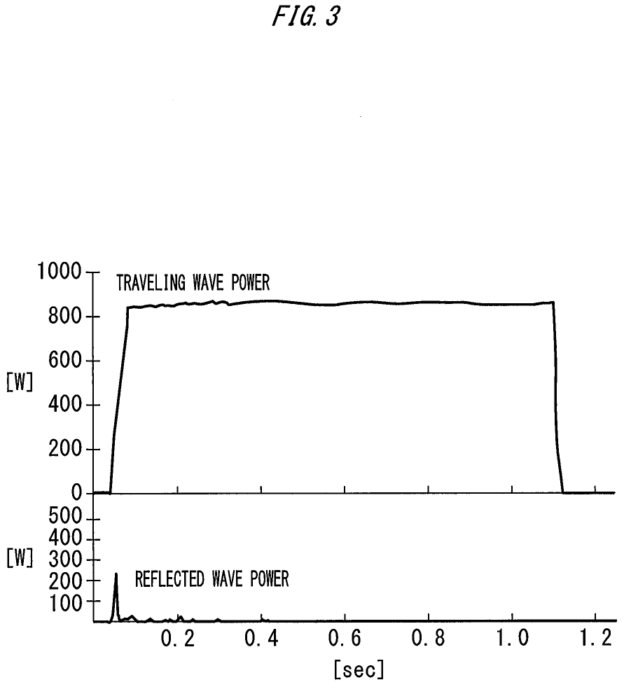

According to further another example, the substrate treatment apparatus can calculate the integral value of the traveling wave power and the integral value of the reflected wave power, and determine whether the process is performed accurately in compliance with a ratio between the integrated values. For example, the controller issues an alarm to the user when a ratio of the integrated value of the reflected wave power to the integrated value of the traveling wave power has exceeded a predetermined value. An example of such a control will be described below with reference to FIG. 3.

FIG. 3 is a diagram which shows an example of waveforms of a traveling wave power and a reflected wave power. Here, the traveling wave power and the reflected wave power are shown when a traveling wave power of 840 W has been applied for 1 second. In this example, at the moment when a radio frequency power has been applied, a reflected wave power of approximately 220 W is generated, and a ratio of the reflected wave power to the traveling wave power is approximately 26%. It is assessed that the maximum value of the reflected wave power is large, but the time period during which the reflected wave power is generated is as extremely short as approximately 15 msec, and does not give an effective influence. In this example, an integrated value of the traveling wave power is 834.7, and the integrated value of the reflected wave power is 2.86. A ratio obtained by dividing an integrated value of the reflected wave power by a sum of the traveling wave power and the reflected wave power is 0.34% which is sufficiently small, and it can be determined that the reflected wave power does not give an influence on the plasma treatment. In this example, the substrate treatment apparatus confirms that the integrated value is sufficiently small for every pulse of the radio frequency power. According to another example, the substrate treatment apparatus monitors the sum total of integrated values that are obtained from a plurality of pulses or all the pulses which are used for plasma treatment of one wafer.

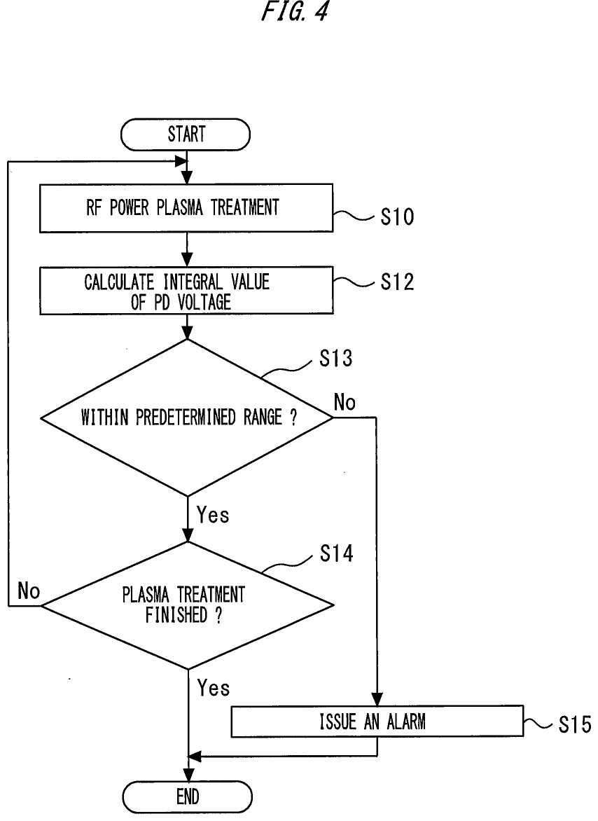

FIG. 4 is a flowchart which shows a substrate treatment method according to another example. In this example, a luminescence intensity of the plasma shall be an object to be monitored. Firstly, in step S10, the plasma treatment is performed. While the plasma treatment is performed, the photodetector 30 outputs information on the luminescence intensity of the plasma to the PMC 20 or another controller. The information on the luminescence intensity of the plasma is, for example, a voltage value which has been converted from the plasma light. This voltage value is referred to as a PD voltage.

In step S12, the PMC 20 or the UPC 19 calculates an integral value of the PD voltage. According to one example, the calculation unit of the UPC 19 calculates the integral value of the PD voltage. According to one example, the calculation unit can calculate the integral values for every one of plasma luminescence that occurs periodically. According to another example, the substrate treatment apparatus can calculate the sum total of integrated values for a plurality of times of plasma luminescence. According to further another example, the substrate treatment apparatus can calculate the sum total of the integral values for all the plasma luminescence which are used for the plasma treatment for one wafer.

In step S13, the substrate treatment apparatus determines whether the calculated integrated value is within a predetermined range. An arbitrary controller can execute this determination. According to one example, the alarm determination unit of the UPC 19 determines whether the integrated value is within a range between an upper limit and a lower limit which are stored in the storage unit or the data storage unit 21. If the integrated value is not within the predetermined range, it means that normal plasma has not been generated, and accordingly the alarm determination unit issues an alarm in step S15. On the other hand, if the integrated value is within the predetermined range, in step S14, the UPC 19 or PMC 20 determines whether to continue the plasma treatment based on the recipe. If the plasma treatment is to be continued, the UPC 19 or PMC 20 returns the process to step S10, and implements the next plasma treatment. Otherwise, the UPC 19 or PMC 20 ends the process.

Instead of determining whether the integrated value is within the predetermined range, the substrate treatment apparatus can determine whether the integrated value does not exceed the upper limit, or whether the integrated value is lower than the lower limit. According to another example, another criterion is employed.

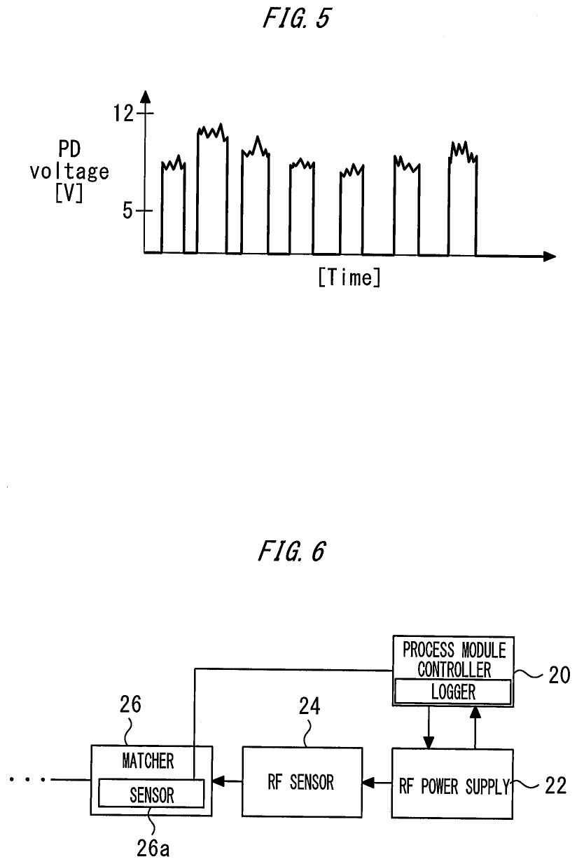

FIG. 5 is a diagram which shows an example of a PD voltage. When monitoring only the presence or absence of the plasma luminescence, the substrate treatment apparatus has only to monitor whether or not the PD voltage has exceeded a threshold value of, for example, 5 V. It is monitored that the PD voltage has exceeded 5 V a predetermined number of times in a predetermined period. When the number of times of detection of the PD voltage exceeding 5 V in the predetermined period is, for example, five times short of the predetermined number of times, the substrate treatment apparatus can issue an alarm. In addition to such monitoring, or instead of such monitoring, in the process described with reference to the above FIG. 4, the integrated value of the PD voltage shall be an object to be monitored. Monitoring of the integrated value makes it possible to detect not only an insufficient luminescence intensity of the plasma, but also an excessive luminescence intensity of the plasma. In addition, the monitoring of the integrated value does not mean monitoring waveform of the PD voltage but means the monitoring of the area, and accordingly, the substrate treatment apparatus can monitor the process with high accuracy.

FIG. 6 is a diagram which shows a structure example of a substrate treatment apparatus according to another example. In this example, the matching box 26 is provided with a sensor 26a, while being based on the structure in FIG. 1. The sensor 26a indirectly detects a voltage that is applied to an electrode such as the shower head 14. According to one example, the sensor 26a outputs a VPP (Volt peak to peak) of the radio frequency power which is applied to the shower head 14, to the PMC 20 or the UPC 19. According to another example, the sensor 26a outputs VDC (Volt direct current) of the radio frequency power which is applied to the shower head 14, to the PMC 20 or the UPC 19.

A controller such as the PMC 20 or the UPC 19 calculates an integrated value of VPP or VDC, and determines whether the integrated value satisfies a criterion. According to one example, the controller compares the integrated value of VPP with a threshold value, and if the integrated value has exceeded the threshold value, issues an alarm. According to another example, when the integrated value of the VDC becomes a minus value, it is considered that an electric discharge occurs at a place other than a space between the parallel plates, and the controller issues an alarm. When monitoring the integrated value of the VDC, the substrate treatment apparatus can monitor the sum total of the integrated values which have been measured during the treatment of one sheet of a wafer, because the VDC can change slowly during the treatment of a wafer. According to another example, the controller can determine whether a sum of a plurality of integrated values satisfies a criterion, which have been obtained in an arbitrary period. According to further another example, another criterion is employed. As for a process after the validity of the integrated value has been determined, the controller continues or terminates the process as described above.

As an example of the plasma-related signal that is a signal which is obtained in association with the plasma treatment, the traveling wave power, the reflected wave power, the luminescence intensity of the plasma, the VPP and the VDC have been described. Another signal may be used as the plasma-related signal According to one example, in order to calculate the integral value of the plasma-related signal, a logger can be used which is provided in the controller or in the outside of the controller, and stores the history of the plasma-related signal. Specifically, the controller cuts out a predetermined range of the data in the logger, and thereby can calculate the integral value. An example of the logger is the data storage unit 21 in FIG. 1.

Monitoring the “integrated value” of the plasma-related signal can enhance the accuracy of process monitoring, compared to the case of monitoring the maximum value, the minimum value or an average value of the plasma-related signal. According to one example, the PMC 20 or the UPC 19 can execute the calculation of the integral value and the monitoring based on the comparison between the integrated value and the reference value or the like, through a software, as a function of its microcomputer.

The RF sensor 24, the photodetector 30 and the sensor 26a have been described as examples of “output device” which outputs the plasma-related signal. Another output device may be used which outputs a plasma-related signal. By monitoring the integrated value of the plasma-related signal, the substrate treatment apparatus can determine whether the plasma treatment has been performed correctly, or whether the plasma process is being performed correctly.

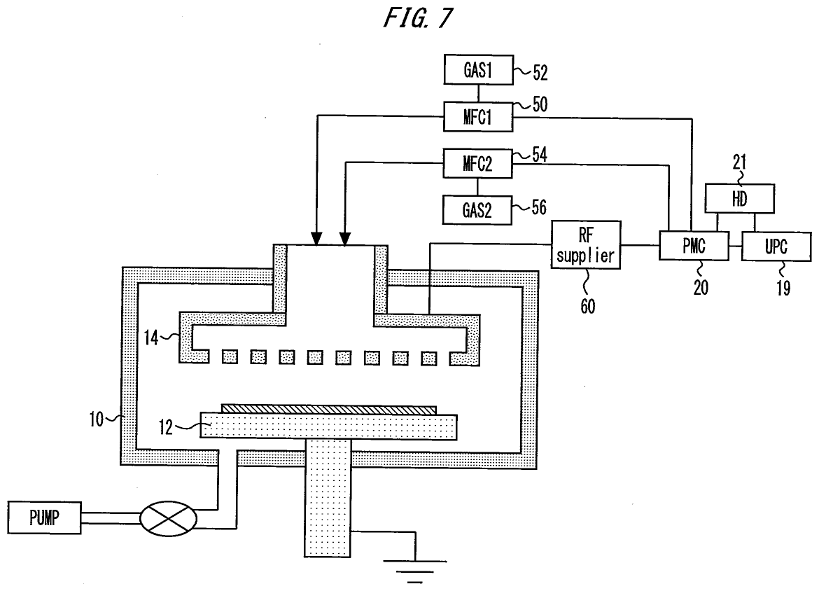

FIG. 7 is a view which shows a structure example of a substrate treatment apparatus according to another example. In this example, a flow amount of a gas shall be an object to be monitored. This substrate treatment apparatus includes: a mass flow controller (MFC) 50 which is controlled by the PMC 20; an MFC 54; and an RF supplier 60. The MFC 50 controls a flow amount of a gas which is supplied into a chamber 10 from a gas source 52. The MFC 54 controls a flow amount of a gas which is supplied into the chamber 10 from a gas source 56. These controls can be performed on the basis of a recipe. The MFCs 50 and 54 can be replaced with an arbitrary gas supplier having the same function.

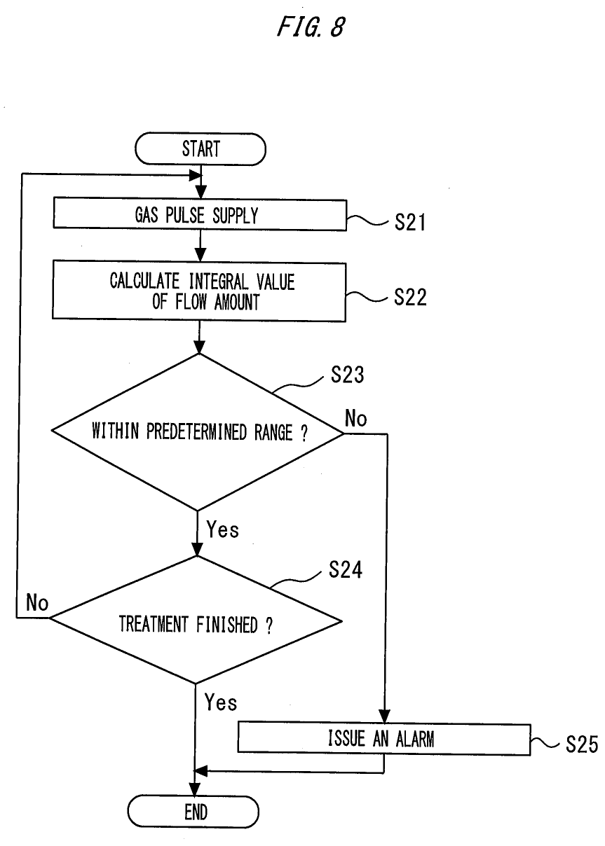

FIG. 8 is a flowchart which shows an example of a substrate treatment method using an apparatus of FIG. 7. In step S21, a predetermined flow amount of a gas pulse is provided into the chamber 10 from at least one of the MFC 50 and the MFC 54. The MFC 50 or the MFC 54 provides information on the flow amount of the gas which has been provided into the chamber by the gas pulse, to the PMC 20, the UPC 19 or another controller. In step S22, the controller calculates an integral value of the flow amount based on the received information, and monitors the integrated value for example as shown in Steps S23 to S25. According to one example, the controller determines whether the integrated value is within a predetermined range, and if the integrated value is not within the predetermined range, issues an alarm.

According to one example, such monitoring of the integrated value can be employed in pulsed CVD that is a process which provides a gas in a pulsed form while plasma is formed. One gas pulse is provided only for such a short time, for example, as few seconds of the first decimal place. According to one example, the PMC 20 issues such a command as to supply a gas pulse having a flow amount of, for example, X ml (X is arbitrary number) for approximately 0.1 seconds to several seconds to a gas supplier; and the gas supplier executes this command. By monitoring the above integrated value, the substrate treatment apparatus can check that an appropriate flow amount of the gas pulse has been provided.

The technological features described in the above certain example can be applied to the apparatuses or methods which are included in other examples.

1. A substrate treatment apparatus, comprising:
an output device configured to output a plasma-related signal which is a signal obtained in association with plasma treatment; and
a controller configured to monitor an integrated value of the plasma-related signal.

2. The substrate treatment apparatus according to claim 1, wherein the controller is configured to digitize the integrated value and monitor the digitized integrated value.

3. The substrate treatment apparatus according to claim 1, wherein the output device comprises an RF sensor configured to output signals on which magnitudes of a traveling wave power and a reflected wave power of a radio frequency power are reflected, as the plasma-related signal, to the controller.

4. The substrate treatment apparatus according to claim 3, wherein when a ratio of the integrated value of the reflected wave power to the integrated value of the traveling wave power has exceeded a predetermined value, the controller is configured to notify a user about abnormality.

5. The substrate treatment apparatus according to claim 1, wherein the output device comprises a photodetector configured to output a luminescence intensity of the plasma to the controller as the plasma-related signal.

6. The substrate treatment apparatus according to claim 5, wherein the controller is configured to calculate the integrated value for every one of plasma luminescence which occurs periodically.

7. The substrate treatment apparatus according to claim 6, wherein the controller is configured to determine whether each of the integrated values satisfies a criterion.

8. The substrate treatment apparatus according to claim 6, wherein the controller is configured to determine whether a sum of a plurality of the integrated values satisfies a criterion.

9. The substrate treatment apparatus according to claim 1, wherein the output device comprises a sensor configured to output a VPP (Volt peak to peak) of a radio frequency power which is applied to a shower head, as the plasma-related signal, to the controller.

10. The substrate treatment apparatus according to claim 1, wherein the output device comprises a sensor configured to output a VDC (Volt direct current) of a radio frequency power which is applied to a shower head, as the plasma-related signal, to the controller.

11. The substrate treatment apparatus according to claim 10, wherein the controller is configured to determine whether a sum of a plurality of the integrated values satisfies a criterion.

12. A substrate treatment apparatus, comprising:
a gas supplier configured to provide a gas pulse to a chamber and output information on a flow amount of a gas provided to the chamber by the gas pulse; and
a controller configured to monitor an integrated value of the information on the flow amount.

13. The substrate treatment apparatus according to claim 12, wherein the controller is configured to determine whether the integrated value is within a predetermined range.

14. A substrate treatment method, comprising:
subjecting a substrate to plasma treatment; and
monitoring an integrated value of a plasma-related signal which is a signal obtained in association with the plasma treatment.

15. The substrate treatment method according to claim 14, wherein the plasma-related signal is a signal which is obtained in association with one pulse of a radio frequency power.

16. The substrate treatment method according to claim 14, wherein the plasma-related signal is a signal which is obtained in association with a plurality of pulses of a radio frequency power.

17. The substrate treatment method according to claim 14, wherein the plasma treatment is a part of an ALD process.
